(19) United States
(12) Patent Application Publication
(10) Pub. No.: US 2026/0191001 A1
(43) Pub. Date: Jul. 2, 2026

(54) IMMERSION COOLED INTEGRATED CIRCUIT PACKAGE

(71) Applicant: Microsoft Technology Licensing, LLC, Redmond, WA (US)

(72) Inventors: Kathryn Midori OSEEN-SENDA, Seattle, WA (US); Naval GUPTA, Lynnwood, WA (US); Danhua XU, Bellevue, WA (US); Oscar ABALOS, JR., Puyallup, WA (US); Fang DONG, Issaquah, WA (US)

(21) Appl. No.: 19/004,602

(22) Filed: Dec. 30, 2024

(51) Int. Cl. H01L 23/427; H01L 23/00

(52) U.S. Cl. CPC H10W 40/73; H10W 72/07352; H10W 72/321; H10W 74/15; H10W 90/724; H10W 90/734

(57) ABSTRACT

A two-phase immersion cooling system may include a two-phase immersion cooling container defining a volume. The two-phase immersion cooling system may include an immersion fluid housed in the two-phase immersion cooling container filling at least a portion of the volume. The two-phase immersion cooling system may include at least one computing system that is at least partially submerged in the immersion fluid, such that the at least one computing system includes a printed circuit board, an integrated circuit, a ball grid array that electrically and mechanically couples the integrated circuit to the printed circuit board, and a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid.

### BACKGROUND

### 1. Field

The present disclosure relates generally to information handling systems, and more specifically to integrated circuit packages in immersion cooled information handling systems.

### 2. Description of the Related Art

As information handling systems such as servers, switches, and other computing devices progress, the increasingly high total thermal loads and heat flux density on these systems are becoming challenging to address with standard air-cooling. Two-phase immersion cooling is a method of cooling servers by immersing them into a dielectric fluid. When servers are running and heated up, the fluid boils. The boiling of the immersion fluid converts the fluid from liquid to vapor state and the vapors carry heat from the hardware and rise upwards where a condenser is located to condense the vapors back into the liquid state and the fluid droplets fall back into the tank to boil and vaporize again and this cycle continues. Unlike water, the fluid inside the tank is harmless to electronic equipment and engineered to boil at a lower boiling point than water. The low temperature boil, and consistent fluid temperature surrounding the servers, enables the servers to operate continuously at full power without risk of failure due to overheating.

### SUMMARY

According to one innovative aspect of the subject matter described in this application, a two-phase immersion cooling system, including: a two-phase immersion cooling container defining a volume; an immersion fluid housed in the two-phase immersion cooling container filling at least a portion of the volume; and at least one computing system that is at least partially submerged in the immersion fluid, wherein the at least one computing system includes: a printed circuit board; an integrated circuit; a ball grid array that electrically and mechanically couples the integrated circuit to the printed circuit board; and a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid.

According to another innovation aspect of the subject matter described in this application A system, includes a printed circuit board; an integrated circuit; a ball grid array that electrically couples the integrated circuit to the printed circuit board, wherein the printed circuit board is configured to operate in a vertical orientation with a face of the printed circuit board on which the integrated circuit is electrically coupled with via the ball grid array being substantially perpendicular to ground; and an edge bond that is coupled to the integrated circuit along a perimeter edge of the integrated circuit and the printed circuit board and that creates a fluid barrier, wherein the edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces ground when the printed circuit board is in the vertical orientation.

According to another innovative aspect of the subject matter described in this application, a process of two-phase immersion cooling includes operating at least one computing system that is at least partially submerged in immersion fluid housed in a two-phase immersion cooling container, wherein the at least one computing system includes: a printed circuit board; an integrated circuit; a ball grid array that electrically and mechanically couples the integrated circuit to the printed circuit board; and a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid; and condensing, with a condenser, immersion fluid that is in a vapor state from the operation of the at least one computing system to a liquid state.

The details of one or more implementations of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

The above-mentioned aspects and other aspects of the present techniques will be better understood when the present application is read in view of the following drawings in which like numbers indicate similar or identical elements:

FIG. 1A is a perspective view illustrating an example of a two-phase immersion cooling system, in accordance with some embodiments of the present disclosure;

FIG. 1B is a front view illustrating an example of the two-phase immersion cooling system of FIG. 1A, in accordance with some embodiments of the present disclosure;

FIG. 2 is a schematic view illustrating an example printed circuit board included in the two-phase immersion cooling system of FIGS. 1A and 1B, in accordance with some embodiments of the present disclosure;

FIG. 3 is a schematic view illustrating an example of an integrated circuit package including the printed circuit board of FIG. 2 with integrated circuits mounted via ball grid arrays to the print circuit board and coupled with various edge bond examples, in accordance with some embodiments of the present disclosure;

FIG. 4A is a cross-sectional view taken along line 4A-4A of the integrated circuit package of FIG. 3, in accordance with some embodiments of the present disclosure;

FIG. 4B is a cross-sectional view taken along line 4B-4B of the integrated circuit package of FIG. 3, in accordance with some embodiments of the present disclosure;

FIG. 5 is a schematic view illustrating an example of an integrated circuit package including the printed circuit board of FIG. 2 with integrated circuits mounted via ball grid arrays to the print circuit board and coupled with various underfill examples, in accordance with some embodiments of the present disclosure;

FIG. 6 is a cross-sectional view take along line 6-6 of the integrated circuit package of FIG. 5, in accordance with some embodiments of the present disclosure;

FIG. 7 is a flow diagram illustrating a process of operating the two-phase immersion cooling system with the integrated circuit package of FIG. 3 or FIG. 5, in accordance with some embodiments of the present disclosure;

FIG. 8 is a flow diagram illustrating a process of providing an integrated circuit package of FIG. 3 of FIG. 5, in accordance with some embodiments of the present disclosure;

FIG. 9 illustrates images comparing underneath contamination of non-edgebonded and edgebonded integrated circuit packages during an experiment, in accordance with some embodiments of the present disclosure;

FIG. 10 illustrates images from x-ray florescence comparing underneath contamination of non-edgebonded and edgebonded integrated circuit packages during the experiment of FIG. 9, in accordance with some embodiments of the present disclosure;

FIG. 11 illustrates charts of x-ray florescence spectra comparing elemental quantification of non-edgebonded and edgebonded integrated circuit packages during the experiment of FIG. 9, in accordance with some embodiments of the present disclosure;

FIG. 12 illustrates a table of the mass concentrations of common elements shown in the x-ray florescence spectra of FIG. 11 for non-edgebonded and edgebonded integrated circuit packages during the experiment of FIG. 9, in accordance with some embodiments of the present disclosure;

FIG. 13 illustrates a chart of x-ray florescence spectra comparing elemental quantification of non-edgebonded and edgebonded integrated circuit packages during the experiment of FIG. 9, in accordance with some embodiments of the present disclosure; and

FIG. 14 is a block diagram of an example of a computing system with which the present techniques may be implemented, in accordance with some embodiments of the present disclosure.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the fields of two-phase immersion cooling and integrated circuit packages. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

As discussed above, two-phase immersion cooling is being developed for servers and other computing devices as thermal generation of these devices increases and these computing devices become more difficult to cool with traditional air-cooling systems. However, the life expectancy of servers in two-phase immersion can be shortened. This is due to hardware failures caused by electric shorts between various components. Shorts are mostly seen at ball grid arrays (BGAs), which have higher heat flux solder balls or conduct heat from the circuit board or integrated circuit. This is especially true with neighboring solder balls under the integrated circuits that have a large voltage delta resulting in voltage potentials, which were discovered by the inventors of the present disclosure to be the most common and leading cause of hardware failures. Due to contamination in the immersion fluid, the inventors of the present disclosure discovered whenever the fluid boils at any location on the server, the contaminants present in the fluid are deposited after the fluid evaporated. Due to this localized contamination deposition at the BGA, the contaminants cause electron migration between two solder balls having large voltage potentials causing dendrite growth between the solder balls and eventually lead to shorting events and integrated circuit failure. Most of the failures occur in components such as solid-state drives (SSD), platform controller hubs (PCH), field programmable gate arrays (FPGA), application specific integrated circuits (ASICs), or other integrated circuits or computing device components that would be apparent to one of skill in the art.

Decreasing the level of contaminants is very difficult. Even with continuous filtration inside the tank that reduces contamination levels to be so low that the contaminants are mostly below a limit of detection in gas chromatography, failures still occur. Increasing the size of the filter is also challenging and does not have significant improvement as much of the contamination is local due the materials on the components of integrated circuit entering the immersion fluid and then depositing when that fluid is boiled and evaporated. Some of the major sources of contaminants are cables, connectors, solder paste materials present on the printed circuit boards and inside the immersion tank, and other various components of the computing device and the immersion tank that would be appreciated by one of skill in the art.

The systems and methods of the present disclosure introduce a sealant that at least partially prevents the flow of the immersion fluid in the volume defined by the ball grid array underneath the integrated circuit. In some embodiments, the sealant may include underfill material that completely seals the solder balls from liquid. However, underfilling the BGA and integrated circuit makes removing the integrated circuit, for service or maintenance reasons, very difficult without damaging the integrated circuit. In some embodiments of the present disclosure, the sealant may include a partial underfill where only areas where solder ball voltage potentials between neighboring solder balls and the distance between those solder balls satisfies a voltage potential distance ratio threshold.

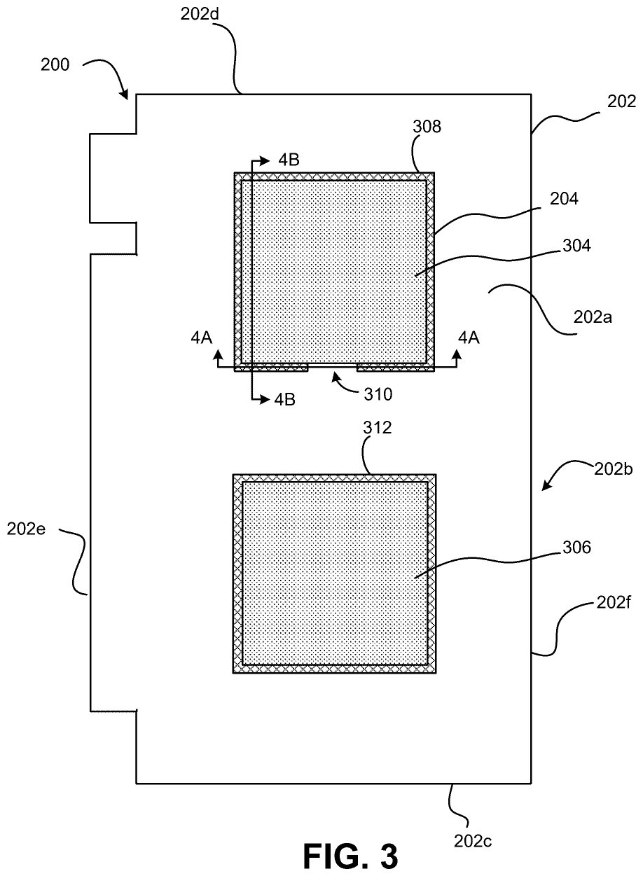

In yet other embodiments of the present disclosure, the sealant may include various edge bond designs. For example, the integrated circuit may be completely edgebonded to the printed circuit board, which prevents liquid from entering the BGA volume between the integrated circuit and the printed circuit board. In another example of an edge bond, a partial edge bond may be applied to the integrated circuit and printed circuit board such that the edge bond, the printed circuit board, and the integrated circuit define an aperture on the downward facing edge of the integrated circuit. As such, as the server is submerged, the air pressure of the air in the BGA volume will prevent the liquid from filling into the BGA volume. Even if the air under the integrated circuit chip diffuses away and the BGA volume fills with immersion fluid, once that immersion fluid boils, a new air pocket should form preventing additional fluid from entering through the aperture. A partial edge bond, as discussed with reference to FIG. 3 below, is beneficial over a complete edge bond as the vent provided by the aperture allows gases to escape to normalize pressure thus minimizing any mechanical stresses and strains on the integrated circuit package due to temperature fluctuations. While a partial edge bond may let some immersion fluid in, an open slot in the edge bond that is placed at the bottom side, specifically for case when computing devices are vertically stacked inside the immersion tank and fluid boils from bottom towards the top, to ensure that if the immersion fluid enters inside the BGA through that edge bonding open slot when the servers are first turned on at the beginning that fluid or gas from the fluid can escaped during operation of the computing devices when heated and prevent any additional fluid from entering inside the BGA while the computing device remains turned on boiling the immersion fluid. As such, each of these embodiments prevents or drastically reduces the amount of immersion fluid entering the BGA volume. As such, new fluid will not be able to boil and deposit contaminants at the solder balls. Furthermore, the embodiments of the present disclosure have negligible effects on cooling the server and integrated circuit packages as much of the heat dissipates from the top of the integrated circuit that is in contact with the fluid.

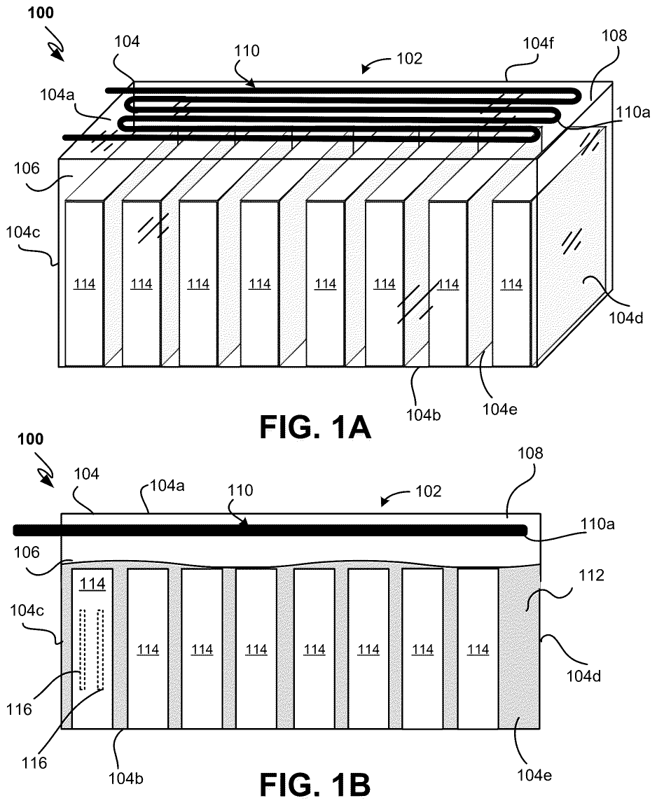

Referring now to FIG. 1, an embodiments of a two-phase immersion cooling system is illustrated. The two-phase immersion cooling system 100 includes a two-phase immersion cooling container 102 having a container chassis 104 that includes a top wall 104a, a bottom wall 104b that is located opposite the container chassis 104 from the top wall 104a, and a pair of side walls 104c and 104d that are located opposite the container chassis 104 from each other and that extend between the top wall 104a and the bottom wall 104b. The container chassis 104 may include a front wall 104e that extends between the top wall 104a, the bottom wall 104b, and the side walls 104c and 104d, and a rear wall 104f that is located opposite the container chassis 104 from the front wall 104e and that extends between the top wall 104a, the bottom wall 104b, and the side walls 104c and 104d. A container volume 106 is defined by the container chassis 104 by the top wall 104a, the bottom wall 104b, the side walls 104c and 104d, the front wall 104e, and the rear wall 104f. The top wall 104a may be hinged or removable such that the side walls 104c and 104d, the front wall 104e, and the rear wall 104f define a container aperture 108. The container aperture 108 may allow for components of the two-phase immersion cooling system 100 to be placed in or removed from the container volume 106.

In various embodiments, the two-phase immersion cooling container 102 may include a condenser 110, which may include a plurality of coils 110a that circulate a cooling fluid such as water or other fluid. The condenser 110 may cool immersion fluid 112 that is in a vapor state and that is housed in the container chassis 104, as illustrated in FIG. 1B. The immersion fluid 112 may be a liquid that has a low boiling point, such that the immersion fluid 112 boils at a lower temperature than water at ambient conditions. The immersion fluid 112 may include fluids that are non-conductive, non-flammable, residue free, or thermally and chemically stable. For example, the immersion fluid 112 may include two-phase dielectrics such as, but not limited to fluorocarbons, hydrocarbons, or other two phase dielectric materials that would be apparent ton one of skill in the art in possession of the present disclosure. In some embodiments, the boiling point of the immersion fluid may be less than the boiling point of water but greater than 20° C. In some embodiments the boiling point may be 45° C.-55° C. . . .

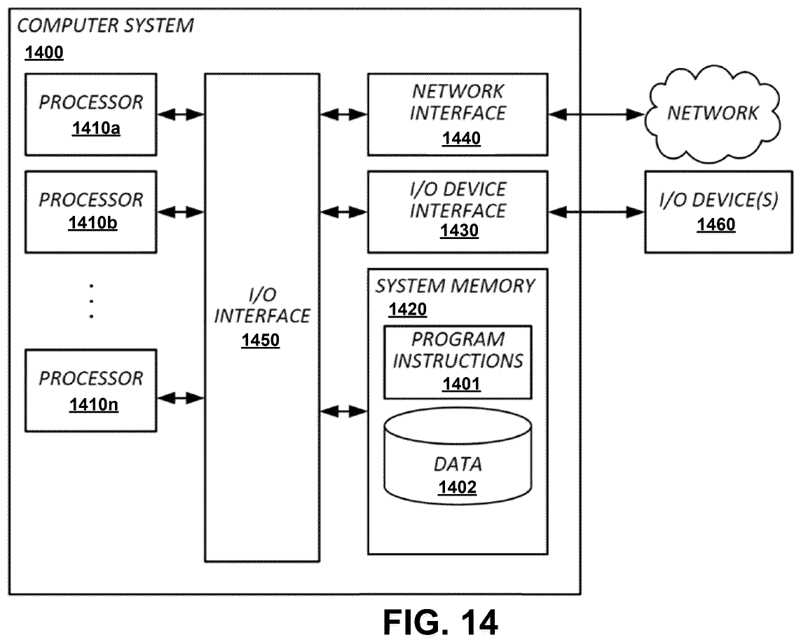

In various embodiments, one or more computing devices 114 may be housed by the container chassis 104 inside the container volume 106. The computing devices 114 may include servers, switches, gateways, or other computing devices/networking devices that would be apparent to one of skill in the art in possession of the present disclosure. In various embodiments, those computing devices may include one or more printed circuit boards 116 that may include one or more integrated circuits electrically coupled or mechanically coupled with the printed circuit boards 116 via a BGA. While simplified computing devices 114 are illustrated one of skill in the art in possession of the present disclosure will recognize that other components such as those described in the example computing system 1400 of FIG. 14, wiring, and the like may be present or a computing device chassis may not be present and merely the printed circuit boards 116 alone without the computing device chassis may be submerged in the immersion fluid 112 without departing from the scope of the present disclosure.

During operation, integrated circuits on the printed circuit boards 116 and other components of the computing devices 114 may operate and perform information processing. During the operations of these computing devices, heat is generated that transfers to the immersion fluid 112 to remove heat from the components. The immersion fluid 112 may be heated to its boiling point. Bubbles will rise towards the top wall 104a of the container chassis 104 and the evaporated immersion fluid will come in contact with the condenser 110, which may carry a cooling fluid such as water. The condenser 110 may cause the evaporated immersion fluid to condense back into liquid form, which may cause droplets of the immersion fluid 112 to form on the condenser 110 that ultimately drop back into the immersion fluid 112. While a specific example of the two-phase immersion cooling container 102 is illustrated and described below, one of skill in the art will recognize that the teachings of the present disclosure will be beneficial to other two-phase immersion cooling container systems including a variety of containers and/or other container apertures that may be on any of the walls 104a-104f, and thus systems including those two-phase immersion cooling container systems will fall within the scope of the present disclosure as well. Furthermore, the two-phase immersion cooling system 100 may include other components that are in the two-phase immersion cooling container 102 such as a fluid filtration system, sensors, or other components that would be apparent to one of skill in the art in possession of the present disclosure.

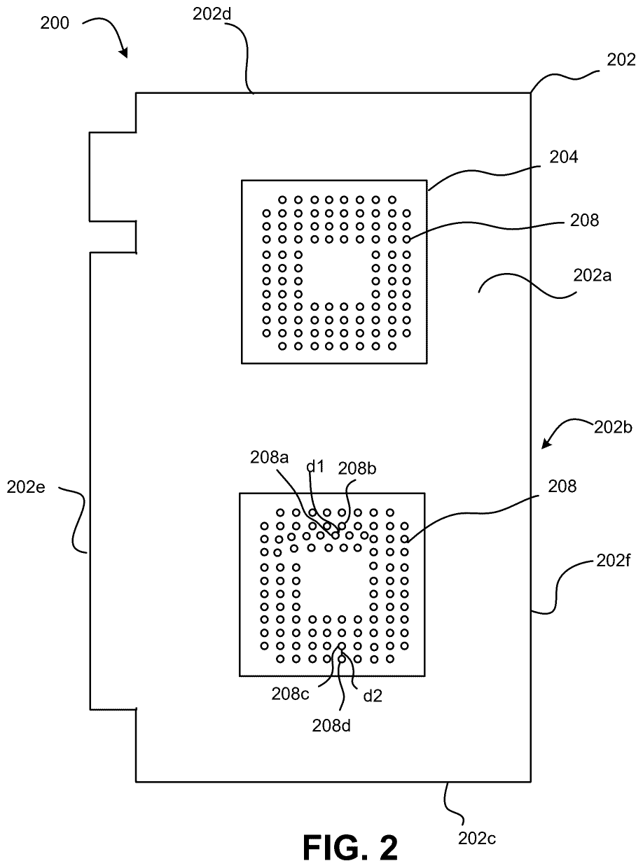

FIG. 2 illustrates an example printed circuit board 200, which may be the printed circuit board 116 of FIG. 1B. The printed circuit board 200 may include a board base 202 having a top surface 202a, a bottom surface 202b (not visible) that is located opposite the board base 202 from the top surface 202a, a front edge 202c extending between the top surface 202a and the bottom surface 202b, a rear edge 202d located opposite the board base 202 from the front edge 202c and extending between the top surface 202a and the bottom surface 202b, and a pair of side edges 202e and 202f that are located opposite each other on the board base 202 and that each extend between the top surface 202a, the bottom surface 202b, the front edge 202c, and the rear edge 202d. The board base 202 may include one or more pad arrays 204 or 206 that may include a plurality of pads (each generally referred to as pad 208) for respective solder balls of a BGA on an integrated circuit that is to be mounted to the printed circuit board 200. These pads 208 may be electrically coupled to various traces in the printed circuit board 200 for carrying out the electrical exchanges with the integrated circuit and other components and connectors on the printed circuit board.

In various embodiments, the pads 208 may be uniformly spaced in a grid like fashion such as on pad array 204. However, in pad array 206, some of the pads 208 may be closer to each other than other pads in the pad array. For example, a pad 208a and a pad 208b may be of a distance d1 while pad 208c and pad 208d may be separated by a distance d2 that is longer than d1. Furthermore, each of the pads 208 may have a voltage associated with it, which may result in various voltage differentials with neighboring pads. For example, the pad 208a be at 10V while the pad 208b may be at 4V resulting in a 6V differential. In contrast, the voltage differential between pads 208c and 208d may be 1V. The combination of voltage differential and distance may result in various potentials between the solder balls that are ultimately on the pads 208. High potentials result in more favorable conditions for dendrite growth because as contaminants deposit at the solder balls from evaporation of the immersion fluid 112, the contaminants cause electron migration between neighboring solder balls with higher potentials causing the dendrite growth between them. The dendrite growth eventually leads to shorting events and integrated circuit package failure. While printed circuit board 200 is illustrated with only pad arrays for BGAs, one of skill in the art will recognize that the printed circuit board 200 may include various components and designs and not depart from the scope of the present disclosure. For example, the printed circuit board 200 may include a variety of electrical and/or mechanical components that may be provided on the printed circuit board 200 such as a processor socket for a processor, memory devices, a memory slot for a memory card, a basic input output system (BIOS), various types of controllers, a heat sink, a video card slot, power connectors, a northbridge, a southbridge, and/or other board components that would be apparent to one of skill in the art in possession of the present disclosure.

FIG. 3 illustrates the printed circuit board 200 with various integrated circuits coupled with the pad arrays 204 or 206, according to various embodiments of the present disclosure. In the illustrated example, an integrated circuit 304 may be mounted to the pad array 204 via a ball grid array on the integrated circuit 304 through a reflow process. Similarly, an integrated circuit 306 may be mounted to the pad array 204 via a ball grid array on the integrated circuit 306 through a reflow process. A sealant may then be added as discussed above. The illustrated sealant for the integrated circuit package of integrated circuit 304 and the pad array 204 with the ball grid array may include a partial edge bond 308. The partial edge bond 308 may include an epoxy material such as, for example, Zymet UA-2605-B edgebonding material, Vitralit® 90070, or other edgebonding materials that would be apparent to one of skill in the art in possession of the present disclosure. In various embodiments, the partial edge bond 308 may be continuous on edges of the integrated circuit that are facing the rear edge 202d and the side edges 202e and 202f of the board base 202. An edge of the integrated circuit 304 that is facing the front edge 202c may include the partial edge bond 308 such that the partial edge bond 308, the printed circuit board 200 and the integrated circuit 304 define an aperture 310 that exposes a BGA volume defined by the partial edge bond 308, the printed circuit board 200, and the integrated circuit 304 to the flow of a fluid such as a gas or a liquid. In the illustrated example, the printed circuit board 200 is designed such that the front edge 202c of the board base 202 is to face the bottom wall 104b of the container chassis 104 when the printed circuit board 116/200 is inserted into the two-phase immersion cooling container 102. However, if other edges of the printed circuit board 200 are to be facing the bottom wall 104b, then the partial edge bond 308 will be designed to include the aperture 310 on the respective edge of the integrated circuit that corresponds with the edge of the printed circuit board 200 facing the bottom wall 104b. In various embodiments, a length of the aperture 310 may be at least a portion of a length of the corresponding edge of the integrated circuit 304 In various embodiments, the aperture 310 may include noncontinuous sub-apertures such that there are a plurality of sub-apertures along the edge of the integrated circuit corresponding with the front edge 202c of the printed circuit board 200. The sub-apertures may be substantially the same length or different lengths.

With respect to integrated circuit 306 and pad array 206, another example sealant embodiment is illustrated. The sealant in this example may include a complete edge bond 312 where the edge bond is distributed completely around the perimeter of the integrated circuit 306. Thus, the complete edge bond 312 may prevent any fluid (e.g., liquid or gas) from moving between a BGA volume that is the space between the integrated circuit 306, the printed circuit board 200, and the complete edge bond 312.

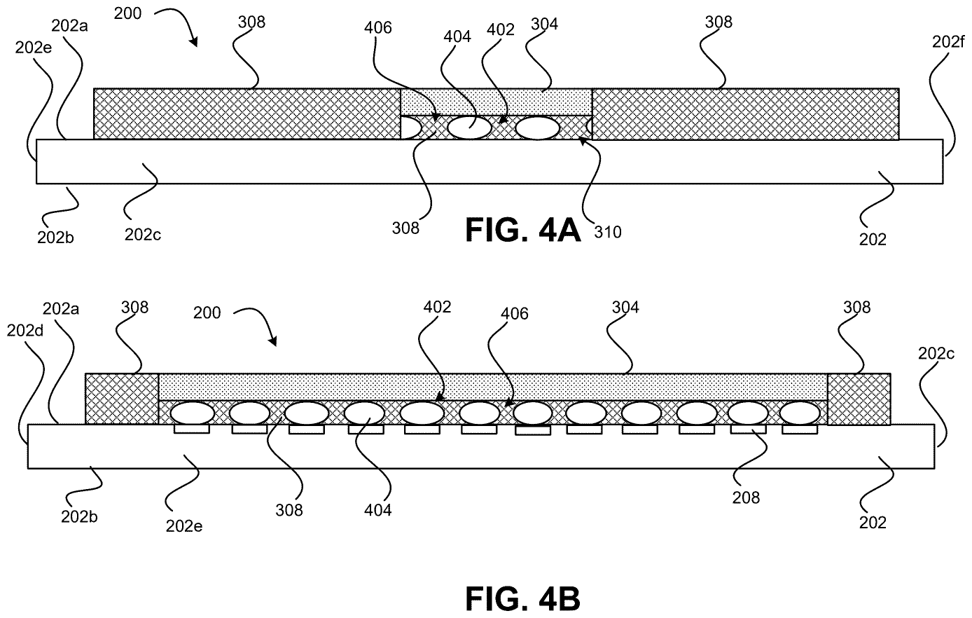

FIG. 4A illustrates a cross-sectional view taken along line 4A-4A of the integrated circuit 304 of FIG. 3, and FIG. 4B is a cross-sectional view taken along line 4B-4B of the integrated circuit 304 of FIG. 3, in accordance with some embodiments of the present disclosure. As can be seen from FIGS. 4A and 4B, the partial edge bond 308, the integrated circuit 304, and the board base 202 define a BGA volume 406 and the aperture 310 that exposes the BGA volume to fluid flow in or out of the BGA volume 406 such that vapor can leave the BGA volume 406 in times of overpressure, but only minimal immersion fluid may enter such that free and continuous fluid flow is minimized The BGA volume 406 may include the ball grid array 402 that includes a plurality of solder balls 404 that are coupled with pads 208 of the pad array 204. While FIGS. 3, 4A, and 4B illustrate an example integrated circuit package with various edge bond examples, one of skill in the art in possession of the present disclosure will recognize other variations of edgebonding without departing from the scope of the present disclosure.

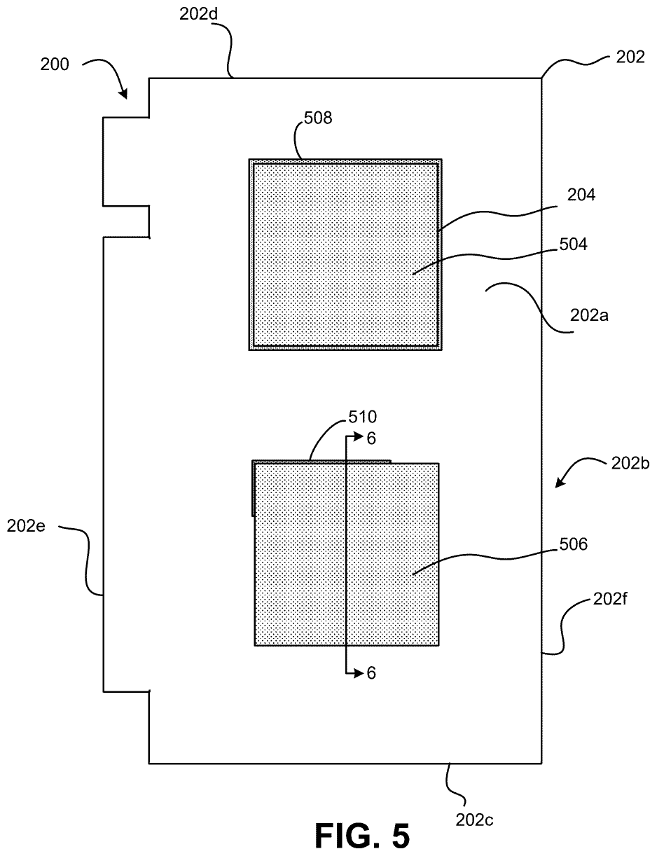

FIG. 5 illustrates the printed circuit board 200 with various integrated circuits coupled with the pad arrays 204 or 206, according to various embodiments of the present disclosure. In the illustrated example, an integrated circuit 504 may be mounted to the pad array 204 via a ball grid array on the integrated circuit 504 through a reflow process. Similarly, an integrated circuit 506 may be mounted to the pad array 204 via a ball grid array on the integrated circuit 506 through a reflow process. A sealant may then be added, as discussed above. The illustrated sealant for the integrated circuit package of integrated circuit 504 and the pad array 204 with the ball grid array may include a complete underfill 508 where underfill material is distributed completely within the BGA volume between the integrated circuit 504 and the pad array 204 of printed circuit board 200. The complete underfill 508 may include an epoxy, acrylic, silicone, or any other underfill materials that would be apparent to one of skill in the art in possession of the present disclosure. Thus, the complete underfill 508 may prevent any fluid (e.g., liquid or gas) from moving between a BGA volume that is the space between the integrated circuit 306, the printed circuit board 200, and the surrounding environment. Furthermore, the complete underfill 508 is a dielectric material that electrically isolates the solder balls from each other, thus preventing dendrites to form between them.

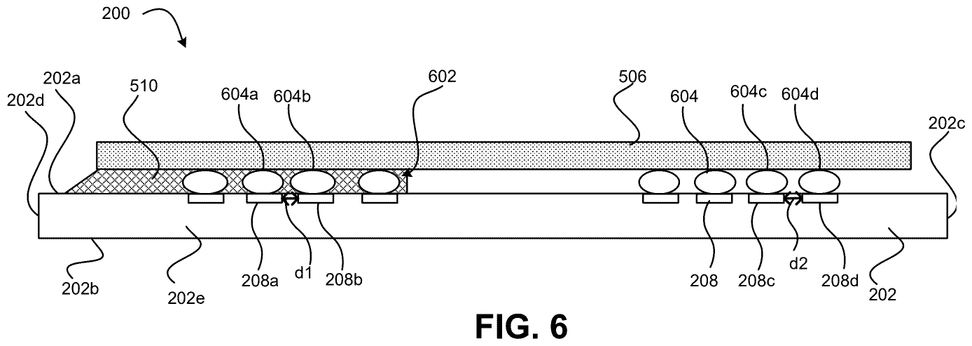

With respect to integrated circuit 506, the sealant may include a partial underfill 510. The partial underfill 510 may be localized to a portion of the ball grid array where the greatest voltage potentials between solder balls are located. With reference to FIG. 6 that illustrates a cross-sectional view taken along line 6-6 of the integrated circuit 506 of FIG. 5, the partial underfill is deposited in the area of a ball grid array 602 where solder balls 604 of the ball grid array 602 have a voltage potential that exceeds a voltage potential threshold. The potential for electrochemical migration of ions and dendrite growth may depend on the type of contaminants and distance between solder balls. As such, the voltage potential threshold may be greater than zero and based on a manufactures preference. For example, the solder ball 604a on pad 204a and the solder ball 604b on pad 204b, which is separated by distance d1 from pad 204a may have a voltage potential that is greater than the voltage potential threshold. Therefore, the partial underfill 510 may fill in the BGA volume surrounding those solder balls to prevent dendrite growth. In contrast, the solder ball 604c on pad 204c and the solder ball 604d on pad 204d, which is separated by distance d2 from pad 204c may have a voltage potential that is less than the voltage potential threshold. As such, those solder balls 604c and 604d may not receive underfill material in the BGA volume surrounding those solder balls 604c and 604d. While FIGS. 5 and 6 illustrate an example integrated circuit package with various underfill examples, one of skill in the art in possession of the present disclosure will recognize other variations of underfilling without departing from the scope of the present disclosure. Furthermore, sealants with a combination of a partial edge bond and a partial underfill are contemplated. For example, the partial edge bond 308 and the partial underfill 510 may be applied to an integrated circuit package.

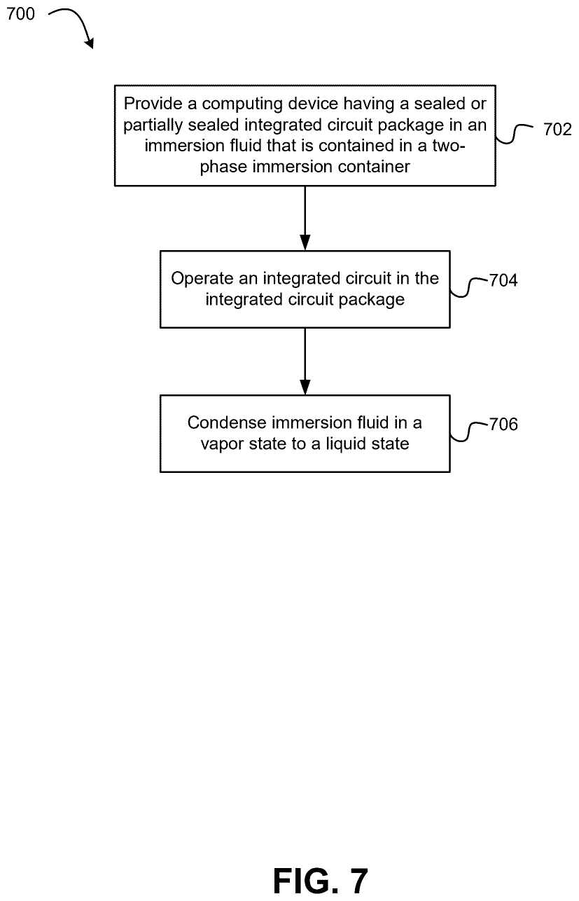

FIG. 7 illustrates a method 700 of use of sealed integrated circuit packages in a two-phase immersion cooling environment. The method 700 may begin at block 702 where a computing device having a sealed or partially sealed integrated circuit package is provided in an immersion fluid that is contained in a two-phase immersion container. In an embodiment, at block 702, a computing device such as the computing device 114 of FIG. 1 may be submerged in the immersion fluid 112 that at least partially fills the container volume 106 defined by the container chassis 104 of the two-phase immersion cooling container 102. The computing device 114 may include the printed circuit board 200, the integrated circuit 304, and the ball grid array 402 such as that electrically or mechanically couples the integrated circuit 304 to pads 208 of the printed circuit board 200. The printed circuit board 200 may be in a vertical orientation such that the top surface 202a and the bottom surface 202b are substantially perpendicular to the bottom wall 104b of the container chassis 104 when the printed circuit board 200 is included in the computing device 114. A sealant, such as an edge bond or an underfill discussed above, may be deposited between the printed circuit board 200 and the integrated circuit 304 such that the sealant substantially prevents fluid flow of the immersion fluid 112 across at least a portion of the solder balls 404 that are included in the ball grid array when the integrated circuit 304 is operating at a temperature that boils the immersion fluid 112. When the integrated circuit package includes the partial edge bond 308, the computing device 114 may be substantially vertically lowered into the immersion fluid 112 to maintain the air present in the BGA volume 406 such that the BGA volume 406 does not fill with the immersion fluid 112 due to the pressure of the air or vapor.

The method 700 may proceed to block 704 where the integrated circuit operates while in the immersion fluid causing the immersion fluid to boil. In an embodiment at block 704, the integrated circuit 304 may operate and perform processing or other operations that cause the integrated circuit 304 to generate heat. The degree of heat generated may be greater than the boiling point of the immersion fluid 112 causing the immersion fluid 112 to boil as the heat transfers from the integrated circuit 304 to the immersion fluid 112. The evaporated immersion fluid may bubble to the surface of the immersion fluid 112 adjacent the top wall 104a and escape into the vapor space of the container volume 106 that is not filled with the immersion fluid 112.

The method 700 may proceed to block 706 where evaporated immersion fluid is condensed to liquid form. In an embodiment, at block 706, the condenser 110 may cool the immersion fluid 112 that is in a vapor state such that the immersion fluid vapor condenses into the immersion fluid 112 again. The condensed immersion fluid deposits back into the pool of the immersion fluid 112 cooling the integrated circuit 304.

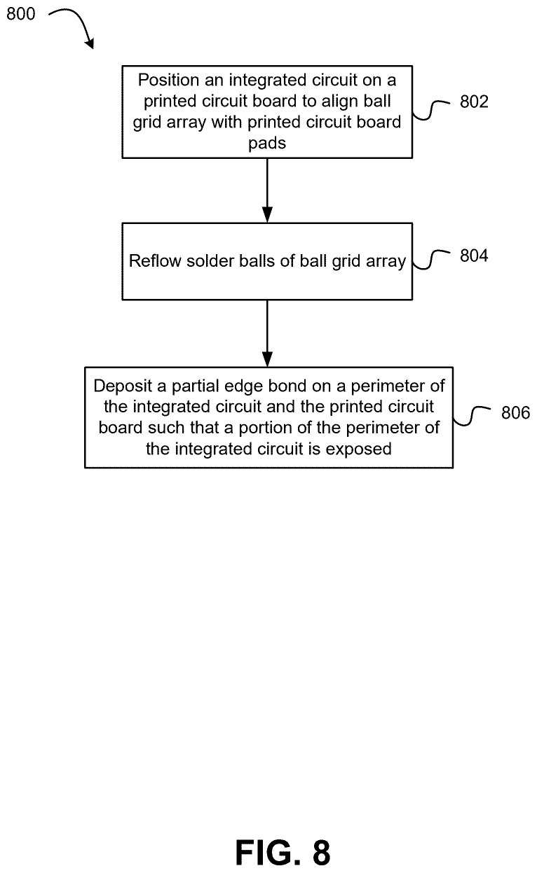

FIG. 8 illustrates a flow diagram of a method of manufacturing the integrated circuit packages discussed herein. The method 800 may begin at block 802 where an integrated circuit is positioned on a printed circuit board such that solder balls of a ball grid array on the integrated circuit are aligned with pads of the printed circuit board. In an embodiment, at block 802, the solder balls 404 of the ball grid array 402 included on the integrated circuit 304 may be aligned with corresponding pads 208 of the pad array 204 on the top surface 202a of the printed circuit board 200.

The method 800 may proceed to block 804 where the solder balls are reflowed to mechanically and electrically couple the printed circuit board to the integrated circuit. In an embodiment, at block 804, the printed circuit board 200 and the integrated circuit 304 may undergo a reflow process that causes the solder balls 404 to melt to electrically and mechanically couple the integrated circuit 304 to the printed circuit board 200 via the ball grid array 402. Once the solder balls melt and cool during the reflow process, the solder balls adhere the integrated circuit 304 to the printed circuit board 200 and provide an electrical connection between the integrated circuit 304 and the printed circuit board 200.

The method may proceed to block 806 where a partial edge bond is deposited on a perimeter of the integrated circuit and the printed circuit board such that a portion of the perimeter of the integrated circuit is exposed. In an embodiment, at block 806, the partial edge bond 308 is deposited on the integrated circuit 304 along a perimeter edge of the integrated circuit 304 and the printed circuit board 200. The partial edge bond 308 creates a fluid barrier and the partial edge bond 308, the integrated circuit 304, and printed circuit board 200 define an aperture 310 that exposes a portion of the perimeter edge of the integrated circuit and exposes the ball grid array 402 to fluid flow. The aperture 310 and the portion of the perimeter edge of the integrated circuit 304 having the aperture 310 is selected based on an orientation that the printed circuit board 200 will have when installed in the two-phase immersion cooling system 100 such that the aperture 310 faces the bottom wall 104b of the two-phase immersion cooling container 102 when the printed circuit board 200 is installed. The partial edge bond 308 will help provide improved mechanical integrity of the integrated circuit package when operating while still preventing immersion fluid 112 from entering the BGA volume of the ball grid array 402 as either the air pressure of the cavity formed by the partial edge bond 308 will prevent liquid from entering when the printed circuit board 200 is submerged in the immersion fluid 112 or even if the immersion fluid 112 is in the cavity, that immersion fluid 112 will boil off and prevent additional fluid from entering the cavity. Thus, the partial edge bond prevents continuous boiling of the fluid that results in contaminant deposition on the solder balls 404 of the ball grid array 402.

The following describes experimental results when testing an integrated circuit package that included the integrated circuit 304 and partial edge bond 308 of FIG. 3 operated in a two-phase immersion cooling container. Specifically, 10 servers were operated inside a two-phase immersion cooling container system an two-phase immersion fluid. Each server contained one FPGA card. Out of 10 FPGA cards, 7 were edgebonded and 3 were kept as original non-edgebonded for comparison study post experiment. A stress tool was run throughout the test for 42 days to stress the system at technical data package (TDP) levels to maximize the fluid boiling and contamination deposition while keeping filtration running continuously running 24 hours per day for the duration of the experiment.

Telemetry was collected throughout the test to track the test progress and ensure the fluid was boiling inside the two-phase immersion cooling container. Some of the telemetry datapoints collected included CPU operational temperature, PCH, DIMM, PSU temperature, immersion fluid temperature, and blade power usage.

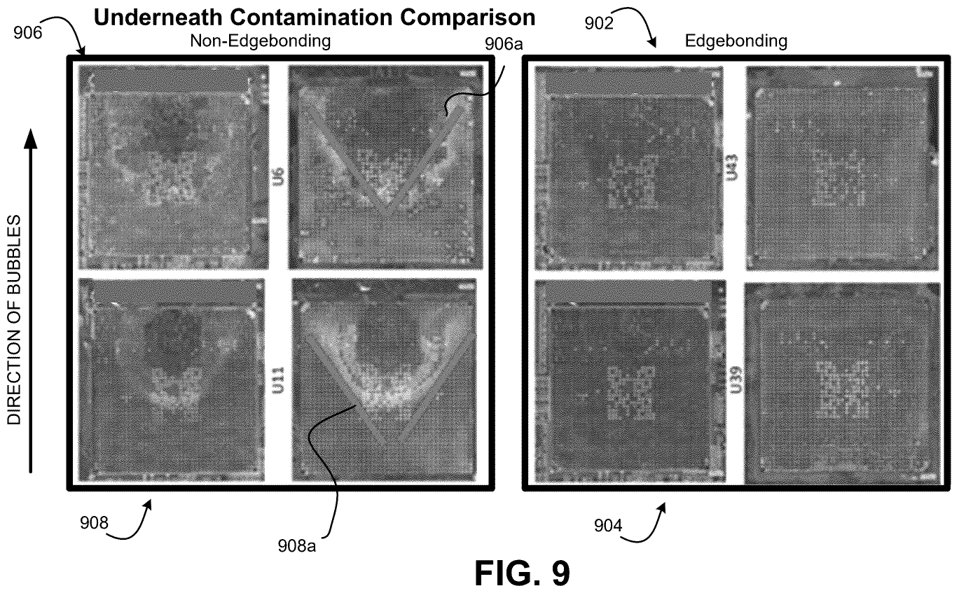

In summary, all 10 FPGAs were evaluated and the partial edge bond 308 was found effective to prevent the internal contamination but not making contamination-free. All 10 FPGAs were evaluated through microscopic inspections. FIG. 9 illustrates photos of the edgebonded integrated circuit packages 902 and 904 versus the non-edgebonded integrated circuit packages 906 and 908. As can be seen from the photos, it is evident that the partial edge bond 308 significantly reduces the contamination deposition. The V-shape patterns 906a and 908a visible are created by the contaminants as the contaminants deposit along the liquid/vapor line

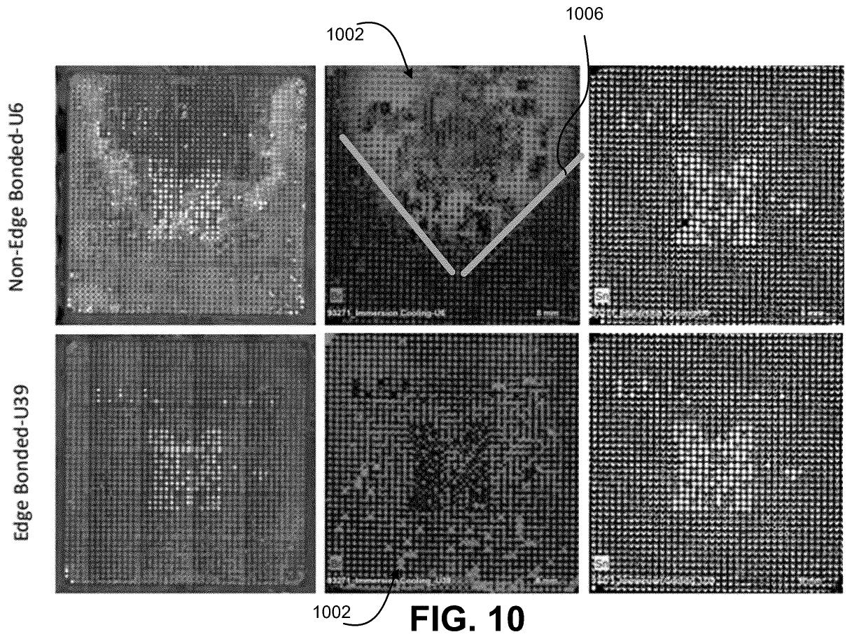

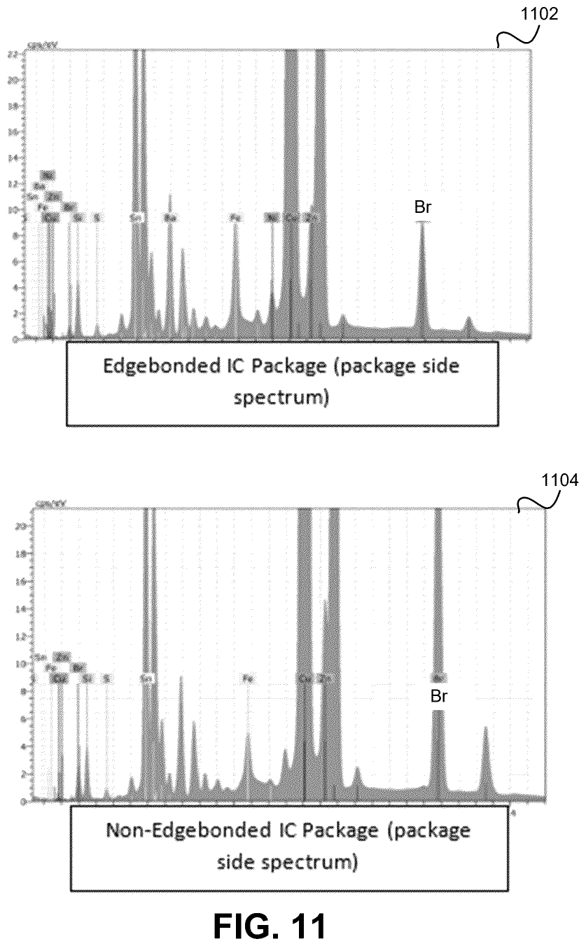

To make a quantitative comparison of contamination level or concentration, X-ray Florescence (XRF) from Bruker with M4+ Model was applied in this study. All commonly distinguishable elements from spectra are listed and mass percentages are tabulated for calculation. A spectrum acquired from a unit without the immersion process was set up as baseline for internal calibration and correction. In XRF analysis, bromine (Br) within contaminants is recognized as a signature element being identified in several previous studies. Thus, this element was specifically targeted in the experiment for quantitative measurement and calculation during XRF elemental mapping analysis. To minimize randomness of contamination distribution, both Tin (Sn) and Copper (Cu) are also mapped as reference concentrations to justify balance of Br concentrations. Referring to FIG. 10, the contamination of Br comparison between the edgebonding and non-edgebonding on BGA surface of FPGAs was examined. As can be seen in FIG. 10, it is evident that the non-edgebonded sample BGA has a significantly higher contamination deposition as shown by the XRF analysis. Bromine (the area shaded and identified by 1002) has been the major contributor found causing the dendrite formation between the solder balls on the BGA leading to shorts. The excess bromine deposition is shown in a non-edgebonded sample following the same v-shape as those in FIG. 9. The same shade color 1004 as 1002 bromine visible in edgebonded sample is the bromine from solder flux material as it also contains bromine. This bromine is still located in its designed location where the bromine in the non-edgebonded is concentrated into a v-shape region 1006. FIG. 11 demonstrates examples of XRF spectra for both edgebonded samples 1102 and non-edgebonded samples 1104. As visible from the XRF spectra, the ‘Br’ content is significantly higher in non-edgebonded samples.

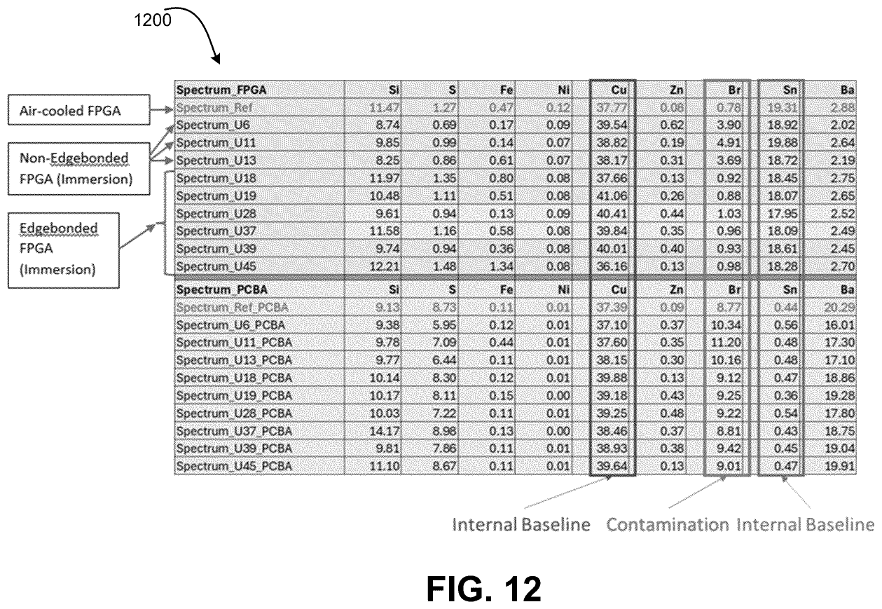

FIG. 12 illustrates the mass concentrations of the common elements shown in spectra. In FIG. 12, the distribution of samples is Spectrum_Ref-Air-cooled non-edgebonded FPGA sample. This sample was used as a baseline for comparison. U6, U11, and U13 are the immersion non-edgebonded FPGA samples. U18, U19, U28, U37, U39, and U45 are the immersion edgebonded FPGA samples. As can be seen from the table 1200, non-edgebonded FPGAs had significantly more Br than the edgebonded FPGAs, which were similar to the baseline air-cooled FPGA.

To quantify the amount of contamination between the edgebonded FPGAs and the non-edgebonded FPGAs, subtraction of background of an element is calculated as following formula:

$$C ( element ) = [ C ( f p g a ) - {C}_{o} ( f p g a ) ] + [ C ( p c b a ) - {C}_{o} ( pcba ) ]$$

where C is the total mass concentration of an element detected on XRF spectra for a specific sample. C(fpga) and C(pcba) are the elemental concentrations from both FPGA and PCBA surfaces, respectively. Similarly, Co(fpga) and Co(pcba) are the same elemental concentrations from a non-immersion cooling population detected on both FPGA and PCBA surfaces, respectively.

The justification for internal correction factor is based upon a non-immersion cooling sample as calculated as:

$$θ ( C u ) = \frac{C ( C u )}{{C}_{o} ( C u )} and θ ( S n ) = \frac{C ( S n )}{{C}_{o} ( S n )}$$

where θ is the correction factor of an element while C(element) and Co(element) are elemental concentrations of the element and non-immersion cooling sample, respectively. Thus, the Br concentrations against Cu and Sn are then calculated as:

$$C ( Br ‖ Cu ) = C ( Br ) \cdot θ ( Cu ) and C ( Br ‖ Sn ) = C ( Br ) \cdot θ ( Sn )$$

Based upon baseline subtraction and internal correction against to Sn and Cu, the following Table 1 is populated for Br concentration in average for both edgebonded and non-edgebonded samples. It is important to note that U6, U11, and U13 are non-edgebonded samples. The rest of the samples are edgebonded.

TABLE 1

| Spectrum_Correction | Br/Cu | Br/Sn |
|---|---|---|
| Spectrum_U6 | 4.78 | 4.63 |
| Spectrum_U11 | 6.67 | 6.76 |
| Spectrum_U13 | 4.37 | 4.18 |
| Spectrum_U18 | 0.51 | 0.47 |
| Spectrum_U19 | 0.62 | 0.54 |
| Spectrum_U28 | 0.74 | 0.66 |
| Spectrum_U37 | 0.23 | 0.21 |
| Spectrum_U39 | 0.84 | 0.77 |
| Spectrum_U45 | 0.44 | 0.42 |

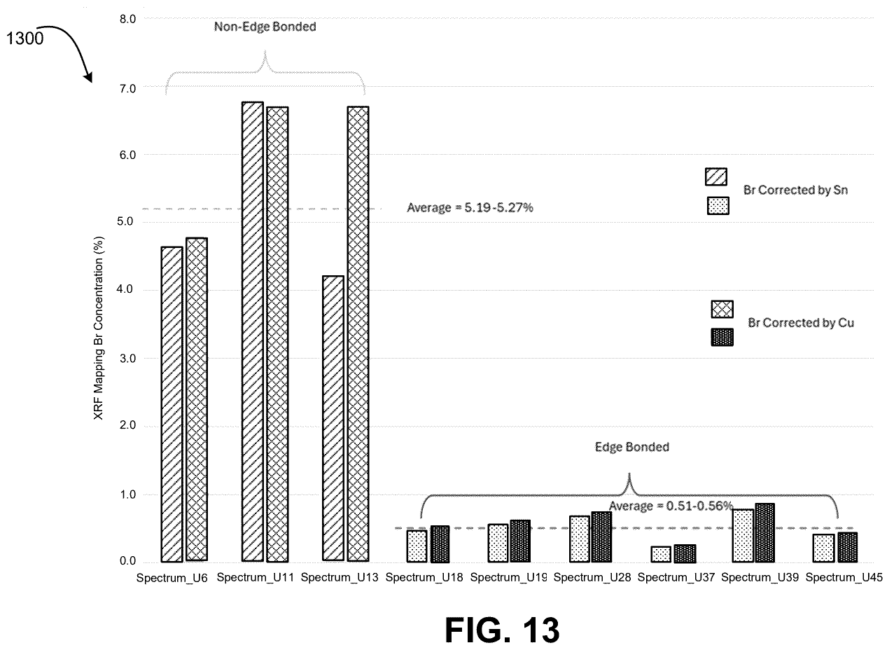

FIG. 13 is a graph 1300 that illustrates the comparison of all these data along with average range from both internal justifications, which demonstrates the significant reduction using both calculations.

$$R ( Br ‖ Cu ) = \frac{{C}_{n e b}^{a} ( Br ‖ Cu ) - {C}_{e b}^{a} ( Br ‖ Cu ) eb}{{C}_{n e b}^{a} ( Br ‖ Cu )}$$

$$And$$

$$R ( Br ‖ Sn ) = \frac{{C}_{n e b}^{a} ( Br ‖ Sn ) - {C}_{e b}^{a} ( Br ‖ Sn ) eb}{{C}_{n e b}^{a} ( Br ‖ Sn )}$$

Where R is reduction factor in comparing edgebonded and non-edgebonded samples in average.

$${C}_{e b}^{a} ( Br ‖ Cu ) and {C}_{n e b}^{a} ( Br ‖ Sn )$$

are average concentrations corrected from edgebonded and non-edgebonded samples, respectively. As can be seen from the graph 1300, there was around 90% reduction (89.3% against Cu calibration and 90.2% against Sn calibration) in contamination at the BGA where the IC package was edgebonded according to the partial edge bond 308 of FIG. 3.

Thus, systems and methods of the present disclosure provide for a sealed or partially sealed integrated circuit package that prevents dendrite growth of contaminants on solder balls of a ball grid array during operation in a two-phase immersion cooling system. The sealant prevents the immersion fluid from boiling at the solder balls, which is the cause of dendrite growth that lead to electrical shorts and integrated circuit failure in conventional computing systems that are cooled with a two-phase immersion process. As such, the systems and methods of the present disclosure increase the longevity of servers in a two-phase immersion cooling environment and reduce downtime while maintaining thermal cooling objectives and mechanical integrity of an integrated circuit package.

FIG. 14 is a diagram that illustrates an example computing system 1400 in accordance with embodiments of the present technique. The computing devices 114, discussed above, may be provided by the computing system 1400. Various portions of systems and methods described herein, may include or be executed on one or more computing systems similar to computing system 1400.

Computing system 1400 may include one or more processors (e.g., processors 1410a-1410n) coupled to system memory 1420, an input/output I/O device interface 1430, and a network interface 1440 via an input/output (I/O) interface 1450. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 1400. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 1420). Computing system 1400 may be a uni-processor system including one processor (e.g., processor 1410a), or a multi-processor system including any number of suitable processors (e.g., 1410a-1410n). Multiple processors may be employed to provide for parallel or sequential execution. Processes, such as logic flows, may be performed by one or more programmable processors executing one or more computer programs to perform functions by operating on input data and generating corresponding output. Processes may be performed by, and apparatus may also be implemented as, special purpose logic circuitry, e.g., an FPGA (field programmable gate array) or an ASIC (application specific integrated circuit). Computing system 1400 may include a plurality of computing devices (e.g., distributed computing systems) to implement various processing functions.

I/O device interface 1430 may provide an interface for connection of one or more I/O devices 1460 to computing system 1400. I/O devices may include devices that receive input (e.g., from a user) or output information (e.g., to a user). I/O devices 1460 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 1460 may be connected to computing system 1400 through a wired or wireless connection. I/O devices 1460 may be connected to computing system 1400 from a remote location. I/O devices 1460 located on remote computing system, for example, may be connected to computing system 1400 via a network and network interface 1440.

Network interface 1440 may include a network adapter that provides for connection of computing system 1400 to a network. Network interface 1440 may facilitate data exchange between computing system 1400 and other devices connected to the network. Network interface 1440 may support wired or wireless communication. The network may include an electronic communication network, such as the Internet, a local area network (LAN), a wide area network (WAN), a cellular communications network, or the like.

System memory 1420 may be configured to store program instructions 1401 or data 1402. Program instructions 1401 may be executable by a processor (e.g., one or more of processors 1410a-1410n). Instructions 1401 may include modules of computer program instructions for implementing one or more techniques with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 1420 may include a tangible program carrier having program instructions stored thereon. A tangible program carrier may include a non-transitory computer readable storage medium. A non-transitory computer readable storage medium may include a machine readable storage device, a machine readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random access memory (SRAM), synchronous dynamic RAM (SDRAM)), bulk storage memory (e.g., CD-ROM or DVD-ROM, hard-drives), or the like. System memory 1420 may include a non-transitory computer readable storage medium that may have program instructions stored thereon that are executable by a computer processor (e.g., one or more of processors 1410a-1410n) to cause the subject matter and the functional operations described herein. A memory (e.g., system memory 1420) may include a single memory device or a plurality of memory devices (e.g., distributed memory devices). Instructions or other program code to provide functionality may be stored on a tangible, non-transitory computer readable media. In some cases, the entire set of instructions may be stored concurrently on the media, or in some cases, different parts of the instructions may be stored on the same media at different times.

I/O interface 1450 may be configured to coordinate I/O traffic between processors 1410a-1410n, system memory 1420, network interface 1440, I/O devices 1460, or other peripheral devices. I/O interface 1450 may perform protocol, timing, or other data transformations to convert data signals from one component (e.g., system memory 1420) into a format suitable for use by another component (e.g., processors 1410a-1410n). I/O interface 1450 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 1400 or multiple computing systems 1400 configured to host different portions or instances. Multiple computing systems 1400 may provide for parallel or sequential processing/execution of one or more portions of the techniques.

Those skilled in the art will appreciate that computing system 1400 is merely illustrative and is not intended to limit the scope of the techniques described herein. Computing system 1400 may include any combination of devices or software that may perform or otherwise provide for the performance of the various techniques. For example, computing system 1400 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 1400 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computing system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 1400 may be transmitted to computing system 1400 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present techniques may be practiced with other computing system configurations.

The reader should appreciate that the present application describes several independently useful techniques. Rather than separating those techniques into multiple isolated patent applications, applicants have grouped these techniques into a single document because their related subject matter lends itself to economies in the application process. But the distinct advantages and aspects of such techniques should not be conflated. In some cases, embodiments address all of the deficiencies noted herein, but it should be understood that the techniques are independently useful, and some embodiments address only a subset of such problems or offer other, unmentioned benefits that will be apparent to those of skill in the art reviewing the present disclosure. Due to costs constraints, some techniques disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such techniques or all aspects of such techniques.

It should be understood that the description and the drawings are not intended to limit the present techniques to the particular form disclosed, but to the contrary, the intention is to cover all modifications, equivalents, and alternatives falling within the spirit and scope of the present techniques as defined by the appended claims. Further modifications and alternative embodiments of various aspects of the techniques will be apparent to those skilled in the art in view of this description. Accordingly, this description and the drawings are to be construed as illustrative only and are for the purpose of teaching those skilled in the art the general manner of carrying out the present techniques. It is to be understood that the forms of the present techniques shown and described herein are to be taken as examples of embodiments. Elements and materials may be substituted for those illustrated and described herein, parts and processes may be reversed or omitted, and certain features of the present techniques may be utilized independently, all as would be apparent to one skilled in the art after having the benefit of this description of the present techniques. Changes may be made in the elements described herein without departing from the spirit and scope of the present techniques as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computing system” performing step A and “the computing system” performing step B can include the same computing device within the computing system performing both steps or different computing devices within the computing system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X′ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

In this patent, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques will be better understood with reference to the following enumerated embodiments:

1. A two-phase immersion cooling system, comprising: a two-phase immersion cooling container defining a volume; an immersion fluid housed in the two-phase immersion cooling container filling at least a portion of the volume; and at least one computing system that is at least partially submerged in the immersion fluid, wherein the at least one computing system comprises: a printed circuit board; an integrated circuit; a ball grid array that electrically and mechanically couples the integrated circuit to the printed circuit board; and a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid.

2. The two-phase immersion cooling system of embodiment 1, wherein the sealant includes an underfill structure.

3. The two-phase immersion cooling system of embodiment 2, wherein the underfill structure includes a total underfill structure that encapsulates the plurality of solder balls of the ball grid array in underfill material of the underfill structure.

4. The two-phase immersion cooling system of embodiment 2, wherein the underfill structure includes a partial underfill structure that encapsulates a portion of the plurality of solder balls of the ball grid array.

5. The two-phase immersion cooling system of embodiment 4, wherein the portion of the plurality of solder balls of the ball grid array encapsulated by the partial underfill structure include at least two solder balls that have a voltage potential that exceeds a voltage potential threshold.

6. The two-phase immersion cooling system of any one of embodiments 1-5, wherein the sealant includes a partial edge bond that is coupled to the integrated circuit along a perimeter edge of the integrated circuit and the printed circuit board and that creates a fluid barrier, wherein the partial edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces a bottom wall of the two-phase immersion cooling container when the printed circuit board is in a vertical orientation in the two-phase immersion cooling container.

7. The two-phase immersion cooling system of any one of embodiments 1-6, wherein the sealant that includes a complete edge bond that is continuous along a perimeter edge of the integrated circuit.

8 The two-phase immersion cooling system of any one of embodiments 1-7, wherein the sealant that includes an edge bond and a partial underfill structure.

9. The two-phase immersion cooling system of any one of embodiments 1-8, wherein the sealant includes a means for preventing continuous circulation of the immersion fluid in at least a portion of the plurality of solder balls.

10. A system, comprising: a printed circuit board; an integrated circuit; a ball grid array that electrically couples the integrated circuit to the printed circuit board, wherein the printed circuit board is configured to operate in a vertical orientation with a face of the printed circuit board on which the integrated circuit is electrically coupled with via the ball grid array being substantially perpendicular to ground; and an edge bond that is coupled to the integrated circuit along a perimeter edge of the integrated circuit and the printed circuit board and that creates a fluid barrier, wherein the edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces ground when the printed circuit board is in the vertical orientation.

11. The system of embodiment 10, wherein the aperture includes a plurality of sub apertures.

12. The system of any one of embodiments 10 or 11, wherein a length of the aperture is less than 95% but greater than 5% of a length of the perimeter edge of the integrated circuit that the aperture exposes.

13. The system of any one of embodiments 10-12, wherein at least a pair of solder balls of a plurality of solder balls included in the ball grid array have a voltage potential that is greater than a voltage potential threshold.

14. The system of any one of embodiments 10-13, further comprising an underfill structure between the printed circuit board and the integrated circuit.

15. The system of embodiment 14, wherein the underfill structure includes a partial underfill structure that encapsulates a portion of a plurality of solder balls of the ball grid array.

16. The system of embodiment 15, wherein the portion of the plurality of solder balls of the ball grid array encapsulated by the partial underfill structure include at least two solder balls that have a voltage potential that exceeds a voltage potential threshold.

17. A method of two-phase immersion cooling, comprising: operating at least one computing system that is at least partially submerged in immersion fluid housed in a two-phase immersion cooling container, wherein the at least one computing system comprises: a printed circuit board; an integrated circuit; a ball grid array that electrically and mechanically couples the integrated circuit to the printed circuit board; and a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid; and condensing, with a condenser, immersion fluid that is in a vapor state from the operation of the at least one computing system to a liquid state.

18. The method of embodiment 17, further comprising: lowering the at least one computing system in a substantially vertical direction into the immersion fluid.

19. The method of embodiment 18, wherein the sealant includes a partial edge bond that is coupled to the integrated circuit along a perimeter edge of the integrated circuit and the printed circuit board and that creates a fluid barrier, wherein the partial edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces a bottom wall of the two-phase immersion cooling container when the printed circuit board is in a vertical orientation in the two-phase immersion cooling container.

20. The method of any one of embodiments 17-19, further comprising steps for: installing the sealant on the printed circuit board and the integrated circuit.

What is claimed is:

1. A two-phase immersion cooling system, comprising:
a two-phase immersion cooling container defining a volume;
an immersion fluid housed in the two-phase immersion cooling container filling at least a portion of the volume; and
at least one computing system that is at least partially submerged in the immersion fluid,
wherein the at least one computing system comprises:
a printed circuit board;
an integrated circuit;
a ball grid array that electrically and mechanically couples the integrated circuit to the printed circuit board; and
a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid.

2. The two-phase immersion cooling system of claim 1, wherein the sealant includes an underfill structure.

3. The two-phase immersion cooling system of claim 2, wherein the underfill structure includes a total underfill structure that encapsulates the plurality of solder balls of the ball grid array in underfill material of the underfill structure.

4. The two-phase immersion cooling system of claim 2, wherein the underfill structure includes a partial underfill structure that encapsulates a portion of the plurality of solder balls of the ball grid array.

5. The two-phase immersion cooling system of claim 4, wherein the portion of the plurality of solder balls of the ball grid array encapsulated by the partial underfill structure include at least two solder balls that have a voltage potential that exceeds a voltage potential threshold.

6. The two-phase immersion cooling system of claim 1, wherein the sealant includes a partial edge bond that is coupled to the integrated circuit along a perimeter edge of the integrated circuit and the printed circuit board and that creates a fluid barrier, wherein the partial edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces a bottom wall of the two-phase immersion cooling container when the printed circuit board is in a vertical orientation in the two-phase immersion cooling container.

7. The two-phase immersion cooling system of claim 1, wherein the sealant that includes a complete edge bond that is continuous along a perimeter edge of the integrated circuit.

8. The two-phase immersion cooling system of claim 1, wherein the sealant that includes an edge bond and a partial underfill structure.

9. The two-phase immersion cooling system of claim 1, wherein the sealant includes a means for preventing continuous circulation of the immersion fluid in at least a portion of the plurality of solder balls.

10. A system, comprising:
a printed circuit board;
an integrated circuit;
a ball grid array that electrically couples the integrated circuit to the printed circuit board, wherein the printed circuit board is configured to operate in a vertical orientation with a face of the printed circuit board on which the integrated circuit is electrically coupled with via the ball grid array being substantially perpendicular to ground; and
an edge bond that is coupled to the integrated circuit along a perimeter edge of the integrated circuit and the printed circuit board and that creates a fluid barrier, wherein the edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces ground when the printed circuit board is in the vertical orientation.

11. The system of claim 10, wherein the aperture includes a plurality of sub apertures.

12. The system of claim 10, wherein a length of the aperture is less than 95% but greater than 5% of a length of the perimeter edge of the integrated circuit that the aperture exposes.

13. The system of claim 10, wherein at least a pair of solder balls of a plurality of solder balls included in the ball grid array have a voltage potential that is greater than a voltage potential threshold.

14. The system of claim 10, further comprising an underfill structure between the printed circuit board and the integrated circuit.

15. The system of claim 14, wherein the underfill structure includes a partial underfill structure that encapsulates a portion of a plurality of solder balls of the ball grid array.

16. The system of claim 15, wherein the portion of the plurality of solder balls of the ball grid array encapsulated by the partial underfill structure include at least two solder balls that have a voltage potential that exceeds a voltage potential threshold.

17. A method of two-phase immersion cooling, comprising:
operating at least one computing system that is at least partially submerged in immersion fluid housed in a two-phase immersion cooling container, wherein the at least one computing system comprises:
a printed circuit board;
an integrated circuit;
a ball grid array that electrically and mechanically couples the integrated circuit to the printed circuit board; and
a sealant between the printed circuit board and the integrated circuit that substantially prevents fluid flow of the immersion fluid across at least a portion of a plurality of solder balls that are included in the ball grid array when the integrated circuit is operating at a temperature that boils the immersion fluid; and
condensing, with a condenser, immersion fluid that is in a vapor state from the operation of the at least one computing system to a liquid state.

18. The method of claim 17, further comprising:
lowering the at least one computing system in a substantially vertical direction into the immersion fluid.

19. The method of claim 18, wherein the sealant includes a partial edge bond that is coupled to the integrated circuit along a perimeter edge of the integrated circuit and the printed circuit board and that creates a fluid barrier, wherein the partial edge bond, the integrated circuit and the printed circuit board define an aperture that exposes a portion of the perimeter edge of the integrated circuit and exposes the ball grid array to fluid flow, and wherein the aperture and the portion of the perimeter edge of the integrated circuit faces a bottom wall of the two-phase immersion cooling container when the printed circuit board is in a vertical orientation in the two-phase immersion cooling container.

20. The method of claim 17, further comprising steps for:
installing the sealant on the printed circuit board and the integrated circuit.
